(19) United States
(12) Patent Application Publication
(10) Pub. No.: US 2015/0268392 A1
(43) Pub. Date: Sep. 24, 2015

(54) FILTER-ARRAY-EQUIPPED MICROLENS AND SOLID-STATE IMAGING DEVICE

(71) Applicant: Kabushiki Kaisha Toshiba, Minato-ku (JP)

(72) Inventors: Mitsuyoshi KOBAYASHI, Ota (JP); Risako UENO, Meguro (JP); Kazuhiro SUZUKI, Minato (JP); Honam KWON, Kawasaki (JP); Hideyuki FUNAKI, Shinagawa (JP)

(73) Assignee: Kabushiki Kaisha Toshiba, Minato-ku (JP)

(21) Appl. No.: 14/656,029

(22) Filed: Mar. 12, 2015

(30) Foreign Application Priority Data
Mar. 20, 2014 (JP) 2014-059054

(51) Int. Cl. G02B 5/20; H04N 9/04; H04N 9/64; G02B 3/00

(52) U.S. Cl. CPC G02B 5/201; G02B 5/208; G02B 3/0006; H04N 9/045; H04N 9/646

(57) ABSTRACT

According to an embodiment, a filter-array-equipped microlens includes a filter array and a microlens array. The filter array includes a plurality of first optical filters for selectively transmitting light of an infrared region and a plurality of second optical filters for selectively transmitting light of a first visible wavelength region. The microlens array includes a plurality of microlenses each corresponding to any one of the first optical filters and the second optical filters.

### CROSS-REFERENCE TO RELATED APPLICATION

This application is based upon and claims the benefit of priority from Japanese Patent Application No. 2014-059054, filed on Mar. 20, 2014; the entire contents of which are incorporated herein by reference.

### FIELD

Embodiments described herein relate generally to a filter-array-equipped microlens and a solid-state imaging device.

### BACKGROUND

In regard to an imaging technology in which the distance in the depth direction can be obtained as two-dimensional array information, various methods are being studied such as a method of using a reference beam or a method of performing stereo distance measurement using a plurality of cameras. In recent years, as new distance measuring devices for civilian use, there is a high demand for products having a relatively moderate price.

In such imaging technology for obtaining distances, the triangulation method using parallaxes is known as one of the imaging methods in which a reference beam is not used with the aim of holding down the system cost. As the types of camera capable of implementing the triangulation method, a stereo camera and a multiple camera are known. However, in a stereo camera or a multiple camera, a plurality of cameras is used. Hence, there is a risk of an increase in the failure rate due to an increase in the size of the system or due to an increase in the number of components.

Meanwhile, regarding an imaging optical system, a structure has been proposed in which a microlens array is disposed on the upper side of pixels; a plurality of pixels is arranged in the lower part of each microlens; and an image from a main lens is further formed on the pixels using the microlens array. In this structure, a group of images having parallaxes can be obtained in the units of pixel blocks. The parallaxes enable performing a refocusing operation based on distance estimation and distance information of a photographic subject. An optical configuration in which an image from a main lens is further formed using a microlens array is called a refocus optical system.

One of the factors leading to degradation in the image quality of images taken by an image sensor is a phenomenon called crosstalk in which the light falling on a pixel also enters the neighboring pixels. For example, when crosstalk occurs in a Bayer array implemented in a commonly-used image sensor, there occurs a phenomenon of mixed colors, and the light of a different color component is mistakenly detected in each pixel. As a result, the color reproducibility of the captured image undergoes a decline. Particularly, in the case of an image sensor comprising infrared (IR) detection pixels for the purpose of infrared light detection, infrared light having a longer wavelength than visible light is hard to undergo attenuation inside pixels, thereby easily leading to the occurrence of crosstalk among the neighboring pixels.

In a refocus optical system mentioned above, the light coming from the main lens passes through each microlens, and then falls on the light receiving surface of an image sensor at an angle of incident dependent on the position of the concerned microlens. Thus, in a refocus optical system too, there is a risk of the occurrence of crosstalk among the pixels.

It is an object of the invention to provide a filter-array-equipped microlens and a solid-state imaging device that enable achieving prevention of a decline in the color reproducibility caused due to inter-pixel crosstalk.

### BRIEF DESCRIPTION OF THE DRAWINGS

FIG. 1 is a block diagram illustrating an exemplary configuration of an imaging device that can be implemented in a first embodiment;

FIG. 2 is a diagram illustrating an exemplary configuration of an optical system that can be implemented in the first embodiment;

FIG. 3 is a diagram illustrating another exemplary configuration of the optical system that can be implemented in the first embodiment;

FIG. 4 is a diagram schematically illustrating an example of a RAW image according to the first embodiment;

FIG. 5 illustrates a refocusing operation according to the first embodiment;

FIG. 6 is a diagram illustrating an example of a color filter array having the Bayer arrangement;

FIG. 7 is a diagram illustrating an exemplary configuration of an image sensor having a known configuration;

FIG. 8 is a diagram illustrating an exemplary configuration of an optical system according to the first embodiment;

FIG. 9A is a diagram illustrating an exemplary configuration of the image sensor according to the first embodiment;

FIG. 9B is a diagram illustrating another exemplary configuration of the image sensor according to the first embodiment;

FIGS. 10A and 10B are exemplary shapes of optical filters according to the first embodiment;

FIG. 11 illustrates operations performed by an image processor according to embodiments;

FIG. 12 is a diagram for explaining the smallest repeating unit according to the first embodiment;

FIG. 13 is a diagram for giving concrete explanation of the minimum magnification for reconstruction according to the first embodiment;

FIGS. 14A and 14B illustrate arrangements of color filters according to the first embodiment;

FIG. 15 is a diagram for explaining the positional relationship of the optical filters according to the first embodiment;

FIGS. 16 to 19 are diagrams illustrating specific examples of an optical filter arrangement according to the first embodiment;

FIG. 20 is a block diagram illustrating an exemplary configuration of an imaging device according to a second embodiment;

FIG. 21 is a diagram illustrating an example of timing control performed according to the second embodiment;

FIG. 22 is a diagram for explaining a fact that four types of image data can be obtained from image data obtained in a first time period and a second time period according to the second embodiment;

FIG. 23 is a flowchart schematically illustrating a flow of operations performed in an image signal processor (ISP) according to the second embodiment;

FIG. 24 is a flowchart for explaining distance calculation performed according to the second embodiment;

FIG. 25 is a diagram for explaining a method of calculating the texture quantity of each microlens image according to the second embodiment; and

FIG. 26 is a diagram schematically illustrating a distance map according to the second embodiment.

### DETAILED DESCRIPTION

According to an embodiment, a filter-array-equipped microlens includes a filter array and a microlens array. The filter array includes a plurality of first optical filters for selectively transmitting light of an infrared region and a plurality of second optical filters for selectively transmitting light of a first visible wavelength region. The microlens array includes a plurality of microlenses each corresponding to any one of the first optical filters and the second optical filters.

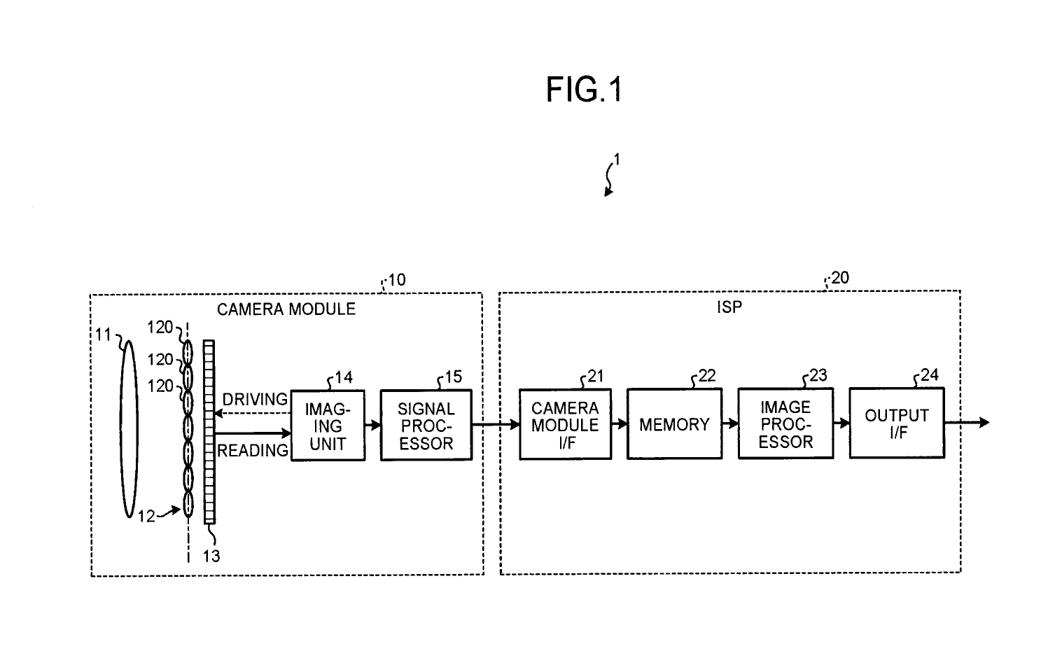

Exemplary embodiments of a filter-array-equipped microlens and a solid-state imaging device are described below. In FIG. 1 is illustrated an exemplary configuration of an imaging device that can be implemented in a first embodiment. With reference to FIG. 1, an imaging device 1 includes a camera module 10 functioning as a lens unit and includes an image signal processor (ISP) 20.

The camera module 10 includes an imaging optical system having a main lens 11; a solid image sensor having a microlens array 12 and an image sensor 13; an imaging unit 14; and a signal processor 15. The imaging optical system includes one or more lenses, and guides the light coming from a photographic subject to the microlens array 12 and the image sensor 13. Of the lenses included in the imaging optical system, the main lens 11 is assumed to be the lens positioned closest to the image sensor 13.

As far as the image sensor 13 is concerned; for example, a charge coupled device (CCD) or a CMOS imager (CMOS stands for Complementary Metal Oxide Semiconductor) is used. Moreover, the image sensor 13 includes a pixel array of a plurality of pixels, each of which converts the received light into an electrical signal by means of photoelectric conversion and outputs the electrical signal.

The microlens array 12 includes a plurality of microlenses 120 arranged according to predetermined rules. Regarding a group of light beams that result in the formation of an image on an image forming surface due to the main lens 11, the microlens array 12 re-forms the image in a reduced manner in pixel blocks each of which includes a plurality of pixels on the image sensor 13 and corresponds to one of the microlenses 120.

Meanwhile, although not illustrated in FIG. 1, a filter array according to the first embodiment is disposed on the side of the image sensor 13 or on the side of the main lens 11 with respect to the microlens array 12. The filter array includes infrared transmission filters that selectively transmit light of the infrared region. Besides, the filter array is configured with optical filters of a plurality of types, each of which is configured to correspond to one of the microlenses 120.

As a result of using an infrared transmission filter, it becomes possible to deal with imaging in the dark such as imaging during nighttime or imaging inside a room.

Among a plurality of types of optical filters included in the filter array, the optical filters other than the infrared transmission filters can be, for example, a plurality of color filters that separate the three primary colors of red (R), green (G), and blue (B). However, that is not the only possible case. Alternatively, the optical filters other than the infrared transmission filters can be colorless filters (called white color filters) that transmit light of the visible light region. Still alternatively, instead of using colorless filters, it is possible to use color filters which have some portion left open and which transmit light of the visible light region.

Meanwhile, the camera module 10 can be configured in such a way that, for example, the imaging optical system including the main lens 11 is separated from the other portion, thereby making it possible to replace the main lens 11. However, that is not the only possible case. Alternatively, the camera module 10 can be configured as a unit in which the imaging optical system, which includes the main lens 11, and the microlens array 12 are housed in a single housing. In that case, the entire unit including the imaging optical system and the microlens array 12 becomes replaceable.

The imaging unit 14 includes a driver circuit for driving each pixel of the image sensor 13. The driver circuit includes, for example, a vertical selection circuit for sequentially selecting the pixels to be driven in the vertical direction in the units of horizontal lines (rows); a horizontal selection circuit for sequentially selecting the pixels to be driven in the vertical direction in the units of columns; and a timing generator that drives the vertical selection circuit and the horizontal selection circuit at various pulses. The imaging unit 14 reads, from the pixels selected by the vertical selection circuit and the horizontal selection circuit, the electrical charge obtained by means of photoelectrical conversion of the received light; converts the electrical charge into electrical signals; and outputs the electrical signals.

With respect to the analog electrical signals output from the imaging unit 14; the signal processor 15 performs gain adjustment, noise removal, and amplification. Moreover, the signal processor 15 includes an A/D conversion circuit for converting the processed signals into digital signals and outputting them as image data of a RAW image.

The ISP 20 includes a camera module I/F 21, a memory 22, an image processor 23, and an output I/F 24. The camera module I/F 21 is an interface for signals with respect to the camera module 10. The image data of a RAW image that is output from the signal processor 15 of the camera module 10 is stored in, for example, the memory 22, which is a frame memory, via the camera module I/F 21.

Of the image data stored in the memory 22, based on the image data which is formed on the basis of the light coming from the microlens array 12 and the color filter array; the image processor 23 performs a refocusing operation in which the image of the area corresponding to each microlens is enlarged and the images are superimposed while shifting positions thereof, and obtains a refocused image that has been reconstructed (described later). Then, the refocused image is output from the output I/F 24 and is either displayed on a display device (not illustrated) or stored in an external memory medium.

Meanwhile, instead of storing the image data in the memory 22, it can be stored in an external memory medium. In that case, the image data read from the external memory medium is stored in the memory 22 via, for example, the camera module I/F 21. Then, the image processor 23 performs the refocusing operation with respect to that image data. Thus, it becomes possible to obtain a refocused image at a desired timing.

Optical System Implementable in First Embodiment

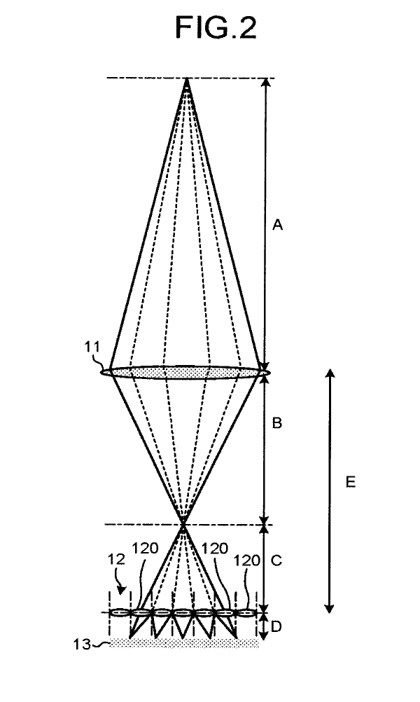

Given below is the explanation of an optical system that can be implemented in the first embodiment. Herein, the optical system includes the main lens 11, the microlens array 12, and the image sensor 13. In FIG. 2 is illustrated an exemplary configuration of the optical system that can be implemented in the first embodiment. With reference to FIG. 2, a distance A indicates the distance between the main lens 11 and a photographic subject; and a distance B indicates the image forming distance for the main lens 11. Moreover, a distance C indicates the shortest distance between the image forming surface of the main lens 11 and each microlens of the microlens array 12; and a distance D indicates the distance between the microlens array 12 and the image sensor 13. Meanwhile, the main lens 11 has a focal distance f, and each microlens 120 has a focal length g. Herein, for the purpose of illustration, with respect to the optical axis, the side of the photographic subject is defined as the front side and the side of the image sensor 13 is defined as the backside.

In the optical system, using the light beams coming from the main lens 11, the microlenses 120 disposed in the microlens array 12 form images of all viewpoints on the image sensor 13. Meanwhile, although not illustrated in FIG. 2, with respect to each microlens 120, a color filter for one color of the RGB colors is disposed.

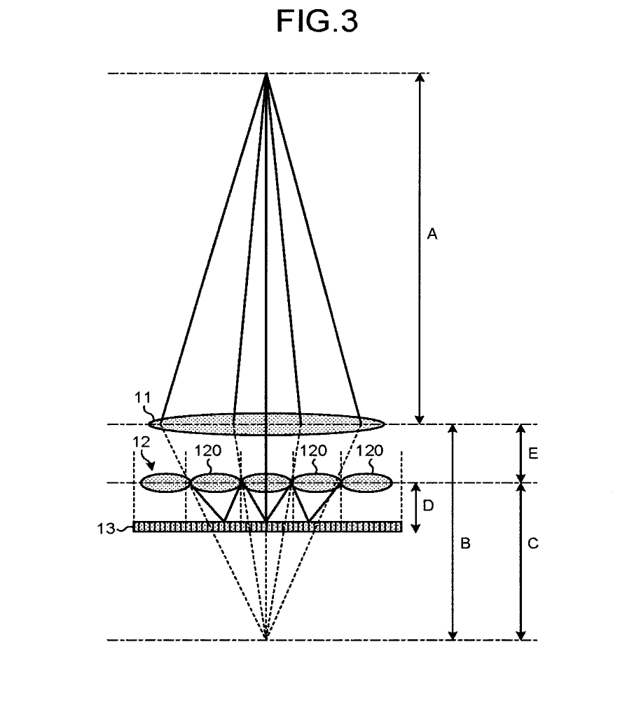

In the example illustrated in FIG. 2, the microlens array 12 is disposed on the backside of the image forming surface of the main lens 11. However, that is not the only possible case. Alternatively, for example, as illustrated in FIG. 3, the microlens array 12 can be disposed on the front side of the image forming surface of the main lens 11.

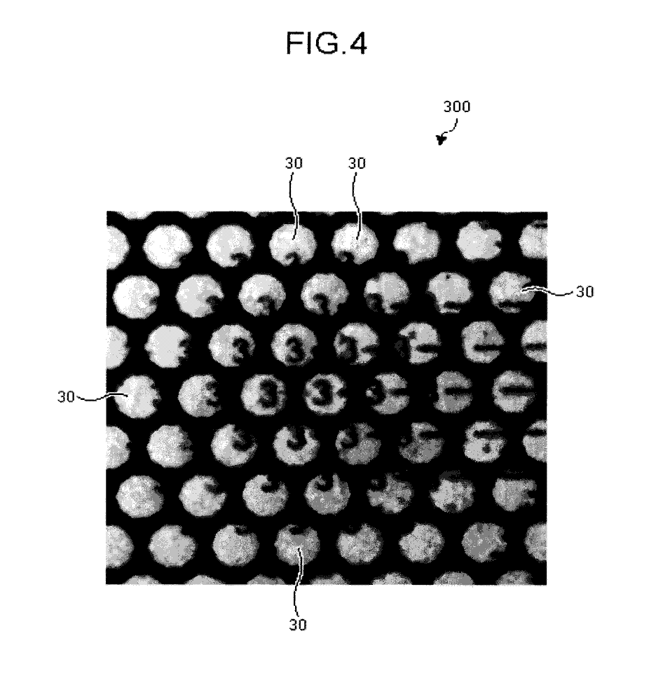

In FIG. 4 is schematically illustrated an example according to the first embodiment of the image data based on the output of the image sensor 13 in the case in which the image forming surface of the main lens 11 is positioned on the backside of the image sensor 13. The signal processor 15 outputs, as image data of a RAW image, an image 300 in which microlens images 30, which are formed on the light receiving surface of the image sensor 13 due to the microlenses 120 of the microlens array 12, are arranged in a corresponding manner to the arrangement of the microlenses 120. With reference to FIG. 4, according to the arrangement of the microlenses 120, the same photographic subject (for example, the number “3”) is captured with a predetermined shift in each microlens image 30.

Herein, it is desirable that the microlens images 30 formed on the image sensor 13 due to the microlenses 120 are formed without any mutual overlapping. Moreover, with reference to FIG. 4, the arrangement represents a hexagonal array in which the microlenses 120 are arranged on hexagonal lattice points in the microlens array 12. However, the arrangement of the microlenses 120 is not limited to this example, and it is possible to have some other arrangement. For example, the microlenses 120 can be arranged on square lattice points. Meanwhile, in the following explanation, it is assumed that the microlens array 12 is disposed on the backside of the image forming surface of the main lens 11 as illustrated in FIG. 2.

Explained below with reference to FIG. 2 is the principle of creating a refocused image. With reference to FIG. 2, addition of the distance B and the distance C is treated as a distance E. If the position of the main lens 11 is fixed, then the distance E is a constant number. Herein, the explanation is given under the assumption that the distance E and the distance D are constant numbers.

In the main lens 11, a relationship given below in Equation (1) according to the lens formula is established between the distance A to the photographic subject, the distance B at which an image is formed by the light coming from the photographic subject, and the focal distance f. In an identical manner, regarding the microlenses 120 of the microlens array 12 too, a relationship given below in Equation (2) according to the lens formula is established.

$$\begin{matrix}\frac{1}{A} + \frac{1}{B} = \frac{1}{f} & ( 1 ) \\ \frac{1}{C} + \frac{1}{D} = \frac{1}{g} & ( 2 )\end{matrix}$$

When there is a change in the distance A between the main lens 11 and the photographic subject, the value of the distance B in the lens formula given in Equation (1) undergoes a change. Based on the positional relationship in the optical system, addition of the distance B and the distance C is equal to the distance E as described above. Moreover, the distance E is fixed. Hence, along with the change in the distance B, the value of the distance C also undergoes a change. Regarding the microlenses 120, as a result of using the lens formula given in Equation (2), along with the change in the distance C, it is found that the value of the distance D also undergoes a change.

Hence, as far as the image formed due to each microlens 120 is concerned, it becomes possible to obtain an image that is the result of reducing the image forming surface, which is a virtual image of the main lens 11, to a magnification N (where, N=D/C). The magnification N can be expressed as Equation (3) given below.

$$N = \frac{D}{C} = \frac{D}{E - B} = \frac{\frac{Cg}{C - g}}{E - \frac{Af}{A - f}} = \frac{Cg ( A - f )}{( C - g ) \{ E ( A - f ) - Af \}} \qquad ( 3 )$$

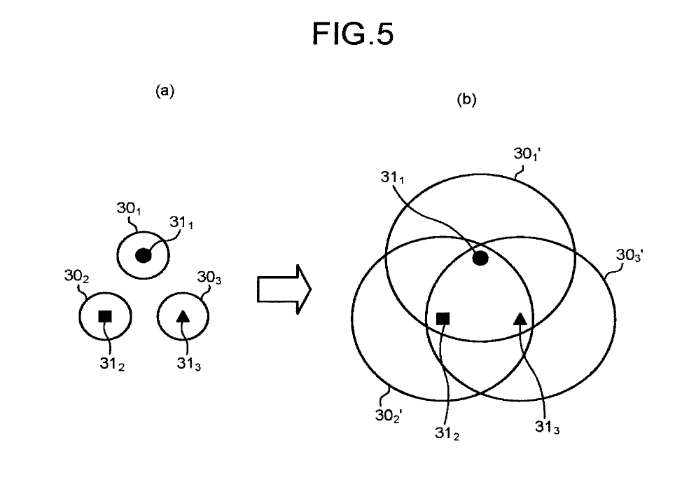

According to Equation (3), it is found that the reduction ratio of the images formed on the image sensor 13 due to the microlenses 120 is dependent on the distance A from the main lens 11 to the photographic subject. Hence, in order to reconstruct the original two-dimensional image; for example, microlens images 30₁, 30₂, and 30₃ that are formed due to the microlenses 120 and that have points 31₁, 31₂, and 31₃ as the respective central coordinates as illustrated in (a) in FIG. 5 are enlarged with the magnification of 1/N as illustrated in (b) in FIG. 5, thereby resulting in the generation of enlarged microlens images 30₁′, 30₂′, and respectively. Then, superimposition and synthesizing of the enlarged microlens images 30₁′, 30₂′, and 30₃′ is performed so that it becomes possible to obtain a reconstructed image that is in focus with the distance A.

During superimposition, regarding the portion at distances other than the distance A, the enlarged microlens images 30₁′, 30₂′, and 30₃′ get superimposed in a misaligned manner. As a result, it becomes possible to achieve a blurring-like effect. Thus, the refocusing operation points to an operation in which an arbitrary position is brought into focus from such microlens images.

Filter Array According to First Embodiment

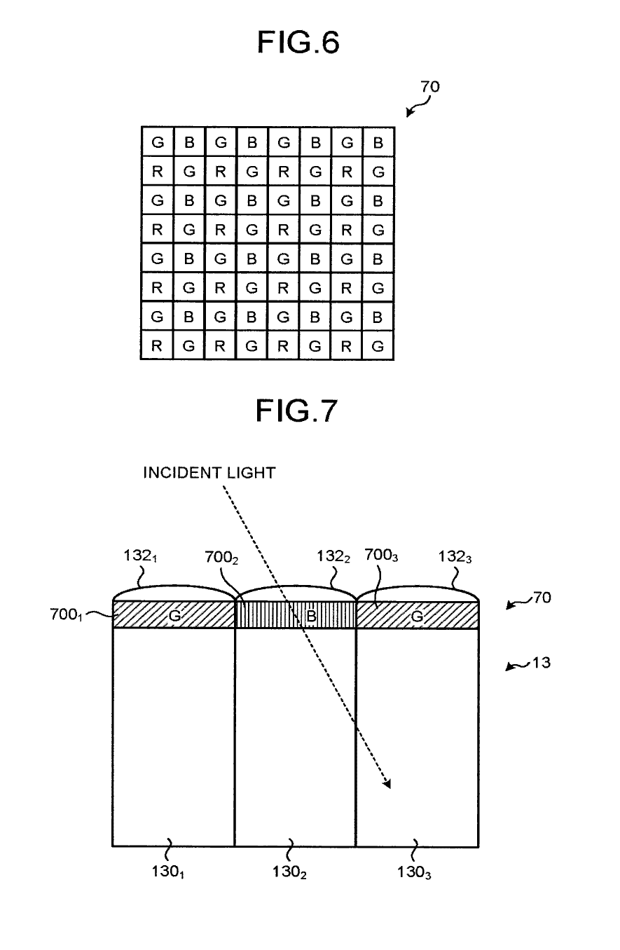

Given below is the explanation of the filter array according to the first embodiment. Firstly, explained with reference to FIGS. 6 and 7 is a known color filter array. In FIG. 6 is illustrated an example of a color filter array 70 having the commonly-used Bayer arrangement. In the color filter array 70 having the Bayer arrangement; as illustrated in FIG. 6, the color filters of RGB colors are configured in a matrix form in which rows having repetition of green, blue, green, blue, . . . are arranged alternately with rows having repetition of red, green, red, green, . . . .

In FIG. 7 is illustrated a cross-section of an exemplary configuration of the image sensor 13 having a known configuration. In the example illustrated in FIG. 7, a green color filter 700₁, a blue color filter 700₂, and a green color filter 700₃ of the color filter array 70 having the Bayer arrangement are disposed corresponding to pixels 130₁, 130₂, and 130₃, respectively, of the image sensor 13. Moreover, in this example, lenses 132₁, 132₂, and 132₃ are disposed on a pixel-by-pixel basis corresponding to the color filters 700₁, 700₂, and 700₃, respectively.

In the case of using an optical system in which the light coming from the main lens 11 is made to pass through the microlens array 12 and then to fall on the image sensor 13 as illustrated in FIG. 2, the angle of incidence with respect to the image sensor 13 goes on increasing toward the outside of the image sensor 13 from the optical axis of the main lens 11. Thus, as illustrated in FIG. 7, for example, the light that passes through the blue color filter 700₂ and falls at an oblique angle on the pixel 130₂ may also fall on the neighboring pixel 130₃.

In this case, not only the light that has passed through the blue color filter 700₃ and the pixel 130₂ falls at an oblique angle on the pixel 130₃; but also the light that has passed through the green color filter 700₃, which is disposed corresponding to the pixel 130₃, falls directly on the pixel 130₃. As a result, inter-pixel crosstalk occurs in the pixel 130₃, thereby leading to a risk of having a decline in the color reproducibility of the captured image.

Particularly, the infrared light, which has a longer wavelength than the visible light, travels for a longer distance from the time of falling on a pixel till being absorbed as compared to the visible light. Hence, the infrared light has a significant impact on the neighboring pixels. For example, consider a case in which the color filter 700₂ illustrated in FIG. 7 is an infrared transmission filter that selectively transmits the infrared light. In that case, as compared to the case in which the color filter 700₂ is a blue color filter, there occurs a greater degree of inter-pixel crosstalk.

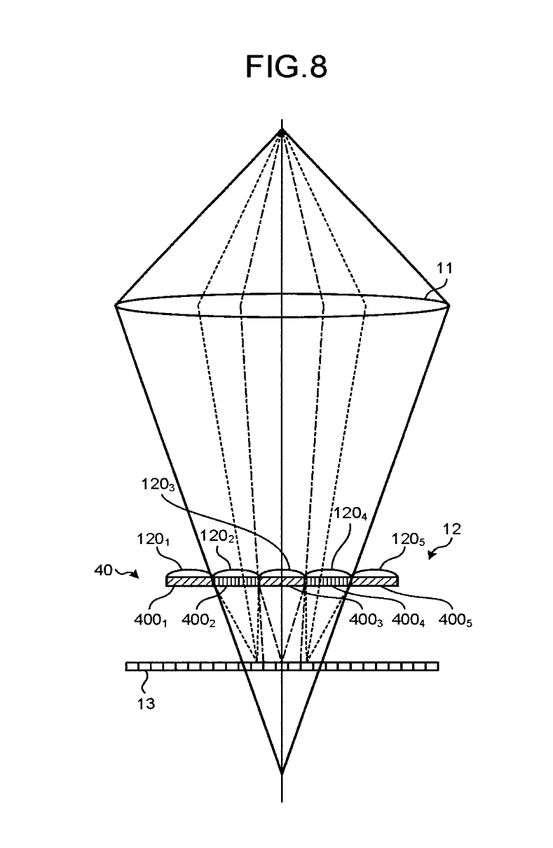

In FIG. 8 is illustrated an exemplary configuration of the optical system according to the first embodiment. The configuration illustrated in FIG. 8 corresponds to the configuration illustrated in FIG. 4. Thus, the common portion with FIG. 4 is referred to by the same reference numerals, and the detailed explanation of that portion is not repeated.

In the first embodiment, with respect to the optical system, a filter array 40 is disposed that includes a plurality of types of optical filters 400₁, 400₂, disposed corresponding to the microlenses 120₁, 120₂, . . . , respectively. In the example illustrated in FIG. 8, for example, the optical filter 400₁ of a first type is disposed corresponding to the microlens 120₁, and the optical filter 400₂ of a second type is disposed corresponding to the microlens 120₂. In an identical manner, optical filters 400₃, 400₄, and 400₅ are disposed corresponding to the microlenses 120₃, 120₄, and 120₅, respectively. Herein, the various types of optical filters include, for example, infrared transmission filters, color filters of all colors, and colorless filters.

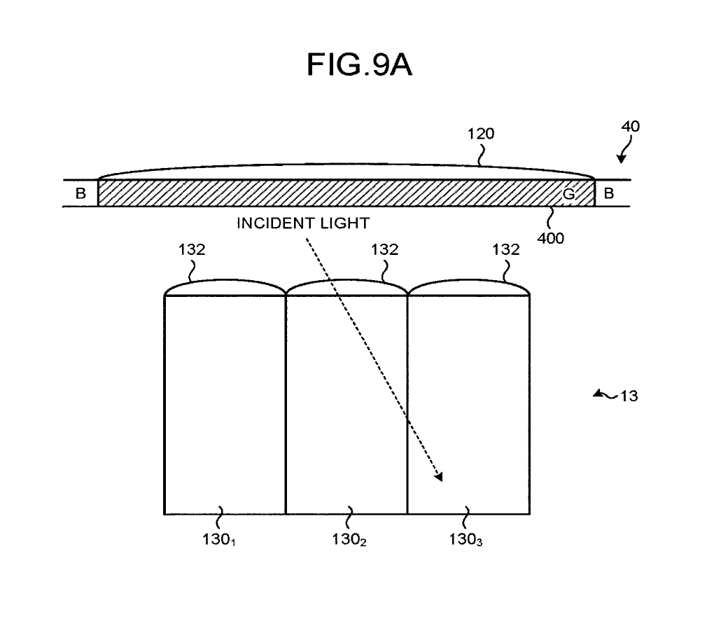

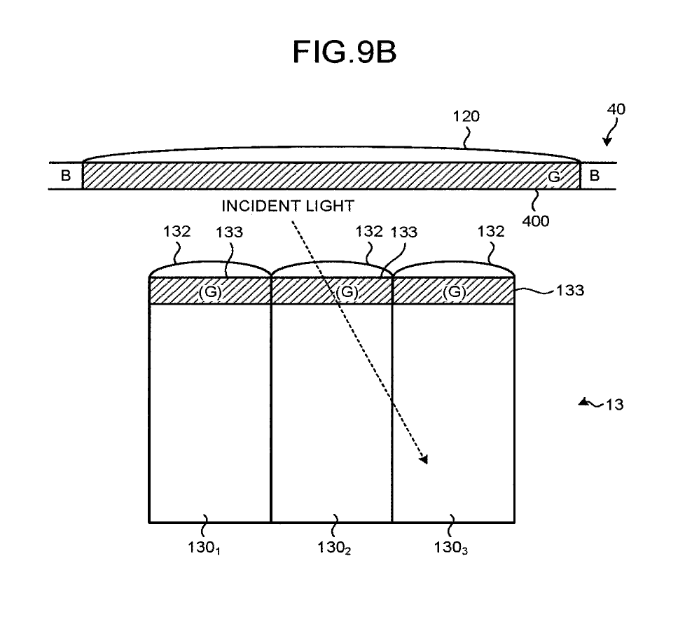

In FIG. 9A is illustrated a cross-section of an exemplary configuration of the image sensor 13 according to the first embodiment. With reference to FIG. 9A, the common portion with FIG. 7 is referred to by the same reference numerals, and the detailed explanation of that portion is not repeated. In the first embodiment, as illustrated in FIG. 9A, from among a plurality of types of optical filters included in the filter array 40, a single type of optical filter 400 (for example, a green color filter) is associated to a single microlens 120. Consequently, the pixels 130₁, 130₂, and 130₃ that receive light from the concerned microlens 120 receive the light which has passed through the same optical filter 400 and which has the same characteristics (for example, the green color).

In this case too, for example, the light that falls on the pixel 130₂ at a predetermined oblique angle also falls on the neighboring pixel 130₂, thereby resulting in inter-pixel crosstalk in the pixel 130₃. However, in this case, the light that directly falls on the pixel 130₃ has passed through the same optical filter 400 through which the light falling obliquely from the neighboring pixel 130₂ had passed. Hence, it becomes possible to prevent a decline in color reproducibility attributed to inter-pixel crosstalk.

Meanwhile, with reference to FIG. 9A, the explanation is given for an example in which the filter array 40 is disposed adjacent to the microlens array 12. However, that is not the only possible case. Alternatively, for example, the microlens array 12 and the filter array 40 can be disposed apart from each other. Moreover, in the example illustrated in FIG. 9A, the microlens array 12 is disposed on the side of the main lens 11, while the filter array 40 is disposed on the side of the image sensor 13. However, alternatively, the microlens array 12 can be disposed on the side of the image sensor 13, while the filter array 40 can be disposed on the side of the main lens 11.

Furthermore, in the example illustrated in FIG. 9A, the optical filters 400 are disposed in units of the microlenses 120. However, that is not the only possible example. For example, as illustrated in FIG. 9B, on-pixel optical filters 133 that are disposed in units of pixels on the pixels 130₁, 130₂, and 130₃ can be combined. With that, it becomes possible to further enhance the color reproducibility by preventing the incident light from other microlenses.

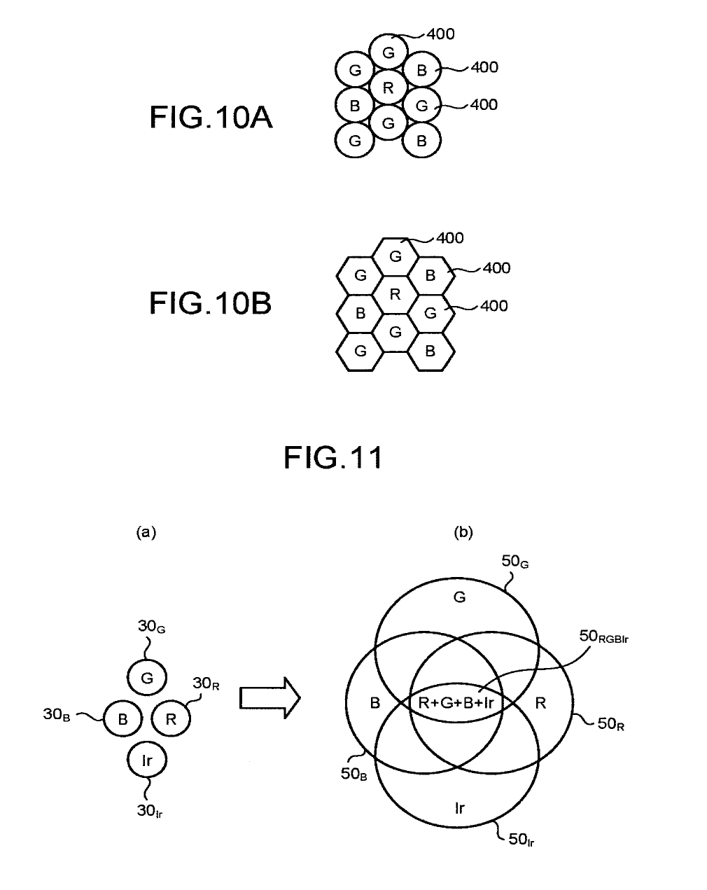

In FIGS. 10A and 10B are illustrated exemplary shapes of the optical filters included in the filter array 40 according to the first embodiment. In FIG. 10A is illustrated an example in which the optical filters 400 are round in shape. In FIG. 108 is illustrated an example in which the optical filters 400 are hexagonal in shape. Thus, the shape of the optical filters 400 can be such that, when they are arranged in a hexagonal array, the corresponding microlenses 120 are covered.

Consider the microlens images 30 in the case in which the filter array 40 includes infrared transmission filters and color filters of RGB colors. In the following explanation, the infrared light is written as Ir color light, and the infrared transmission filters are written as Ir filters. In this case, the microlens images 30 that are formed when the light which has passed through the filter array 40 and the microlens array 12 falls on the image sensor 13 include monochromatic microlens images 30_{R}, 30_{G}, 30_{B}, and 30_{Ir} of RGBIr colors as illustrated in (a) in FIG. 11. With respect to the image data of a RAW image including the microlens images 30_{R}, 30_{G}, 30_{B}, and 30_{Ir}; the image processor 23 enlarges and superimposes each of the microlens images 30_{R}, 30_{G}, 30_{B}, and 30_{Ir} and performs a refocusing operation as explained with reference to FIG. 5.

That is, as illustrated in (b) in FIG. 11, the image processor 23 enlarges the microlens images 30_{R}, 30_{G}, 30_{B}, and 30₁ᵣ and generates enlarged microlens images 50_{R}, 50_{G}, 50_{B}, and 50_{Ir}, respectively. When the enlarged microlens images 50_{R}, 50_{G}, 50_{B}, and 50_{Ir} are superimposed, a superimposition area 50_{RGBIr} represents color images including the RGB colors as well as the Ir color. Then, with respect to the images of RGB colors included in the superimposition area 50_{RGBIr}, the image processor 23 can perform a color image synthesizing operation and obtain color reconstructed images. Moreover, with respect to the image of Ir color included in the superimposition area 50_{RGBIr}, the image processor 23 can perform image processing in a selective manner and obtain an infrared image.

Arrangement in Filter Array

Given below is the explanation about the arrangement of various types of optical filters included in the filter array 40. Examples of the types of optical filters in the filter array 40 include Ir filters and white color filters. Alternatively, examples of the types of optical filters in the filter array 40 include Ir filters and RGB color filters.

Since there are several ways of arranging the various types of optical filters 400 included in the filter array 40, the arrangements are classified. In the following explanation, it is assumed that the arrangements of optical filters in the filter array 40 are expressed in smallest repeating units.

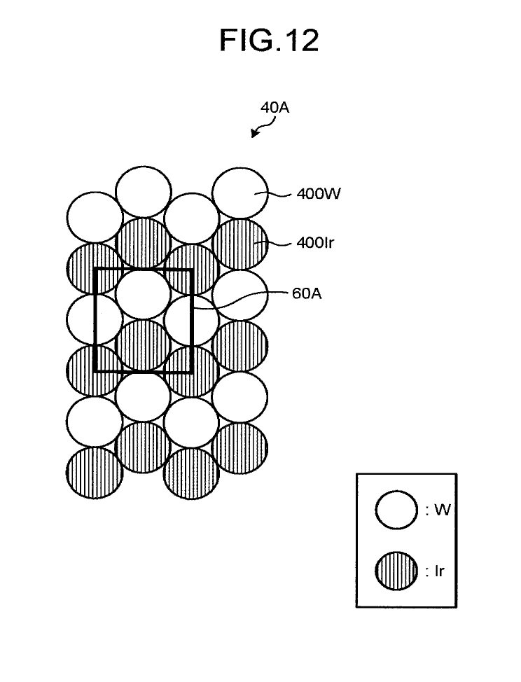

Explained below with reference to FIG. 12 is the smallest repeating unit according to the first embodiment. In FIG. 12 is illustrated a filter array 40A in which Ir filters and white color filters are arranged in a hexagonal lattice. In the example illustrated in FIG. 12, the color component of the Ir color and the color component of the white color have the ratio of 1:1 in the filter array 40A; and a unit area 60A enclosed in a frame border serves as the smallest repeating unit. That is, the arrangement illustrated in FIG. 12 is achieved by tightly laying the arrangement of the unit area 60A.

In the arrangement illustrated in FIG. 12, a group including a linear alignment of two optical filters 400Ir of Ir color and two optical filters 400W of white color is repeatedly placed along that line, and such groups are repeatedly placed adjacent to that line by a shift of one and half filters.

In the arrangement illustrated in FIG. 12, the filter array includes a plurality of first sets. Each first set includes a first array, in which two first optical filters and two second optical filters are alternately arranged in a first direction, and includes a second array, in which two first optical filters and two second optical filters are alternately arranged in a first direction and which is lined with the first array in a second direction that intersects with the first direction. Moreover, the first array and the second array are lined in the first direction by a shift of one and half first optical filters. Furthermore, a plurality of first sets is lined in the second direction.

In the arrangement of various types of optical filters 400 in the hexagonally-arranged filter array 40, the minimum magnification for reconstruction and the distance accuracy assume significance. As an example, consider a case in which the filter array 40 includes four types of optical filters made up of color filters of RGBIr colors. In this case, in a reconstructed image obtained as a result of superimposing the enlarged microlens images 50_{R}, 50_{G}, 50_{B}, and 50_{Ir} that are formed by enlarging the microlens images 30_{R}, 30_{G}, 30_{B}, and 30_{Ir}, respectively, at a particular magnification; the minimum magnification for reconstruction points to the smallest magnification for having all color components (for example, color components of RGBIr colors) constituting a color image with all pixels included in the unit area that serves as the smallest repeating unit. That is, when the microlens images 30_{R}, 30_{G}, 30_{B}, and 30_{Ir} are enlarged at a magnification equal to or greater than the minimum magnification for reconstruction, it becomes possible to obtain an image that includes RGBIr colors at all pixels included in the unit area.

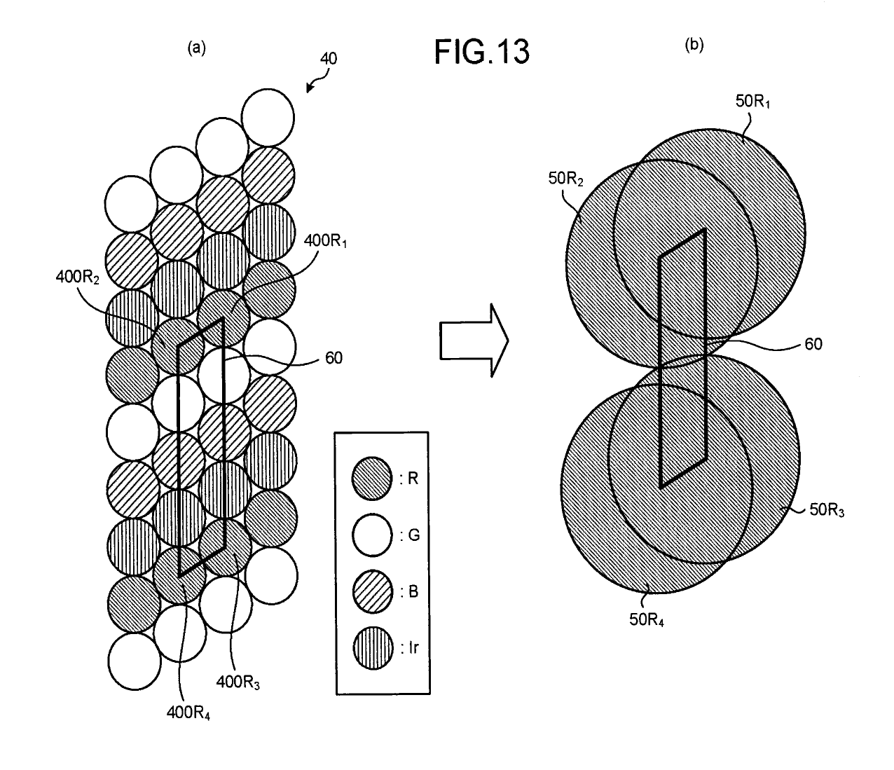

Given below with reference to FIG. 13 is the concrete explanation of the minimum magnification for reconstruction according to the first embodiment. In (a) in FIG. 13 is illustrated an exemplary arrangement in which the color component ratio of RGBIr colors in the filter array 40 is 1:1:1:1.

In the arrangement illustrated in FIG. 13, the filter array includes a plurality of third sets. Each third set includes a fifth array which includes first optical filters arranged in a fifth direction; a sixth array which includes second optical filters arranged in the fifth direction and which is lined with the fifth array in a sixth direction that intersects with the fifth direction; a seventh array which includes third optical filters arranged in the fifth direction and which is lined with the sixth array in the sixth direction; and an eighth array which includes fourth optical filters arranged in the fifth direction and which is lined with the seventh array in the sixth direction. Moreover, a plurality of third sets is lined in the sixth direction.

Herein, focusing on red color filters 400R₁ to 400R₄ at the four corners of a unit area 60 that serves as the smallest repeating unit illustrated in (a) in FIG. 13; an example of enlarged microlens images 50R₁ to 50R₄ that are formed by enlarging the red color filters 400R₁ to 400R₄, respectively, at the minimum magnification for reconstruction is illustrated in (b) in FIG. 13.

In the example illustrated in (b) in FIG. 13, the enlarged microlens images 50R₁ to 50R₄ of red color that are formed at the four corners cover the entire unit area 60, and the inside of the unit area 60 is covered by the color components of RGBIr colors. Herein, the resolution of the reconstructed image decreases in inverse proportion to the square of the minimum magnification for reconstruction. Hence, smaller the minimum magnification for reconstruction, the higher is the possibility of obtaining a reconstructed image of a high resolution.

Given below is the explanation about the distance calculation method. As already described with reference to Equation (3), when there is a change in the value of the distance A illustrated in FIG. 2, the values of the distances B, C, and D also undergo a change. Consequently, the reduction ratio N of the microlens images also undergoes a change.

If Equation (3) is organized for the distance A, then Equation (4) given below is obtained. From Equation (4), the reduction ratio N of the images formed by the microlenses 120 is calculated by means of image matching. Moreover, if the distances D and E and the focal distance f are known, then the value of the distance A can be calculated from Equation (4).

$$A = \frac{( D - NE ) f}{D - NE + Nf} \qquad ( 4 )$$

In the case of the optical system illustrated in FIG. 4, addition of the distance E and the distance C is equal to the distance B. Moreover, the lens formula related to the microlenses 120 is given below in Equation (5). In this case, the relation between the distance A and the reduction ratio N can be expressed using Equation (6) given below.

$$\begin{matrix}- \frac{1}{C} + \frac{1}{D} = \frac{1}{g} & ( 5 ) \\ A = \frac{( D + NE ) f}{D + NE - Nf} & ( 6 )\end{matrix}$$

If Δ′ represents the amount of shift of the microlens images 30 between the microlenses 120 and if a value L represents the center distance between the microlenses 120, then the reduction ratio N can be expressed using Equation (7) according to the geometric relationship of light beams. Thus, in order to obtain the reduction ratio N, the image processor 23 can implement an evaluation function such as the sum of absolute difference (SAD) or the sum of squared difference (SSD), perform image matching with respect to each microlens image 30, and obtain the amount of shift Δ′ between the microlenses 120.

$$N = \frac{{Δ}^{′}}{L} \qquad ( 7 )$$

Meanwhile, according to Equation (7), the minimum magnification for reconstruction is expressed as 1/N.

In the case of using the filter array 40 according to the first embodiment, the image processor 23 performs image matching among the microlens images 30 formed due to the optical filters of same types (same colors). At that time, depending on the arrangement of various types of the filter array 40; due to the distance to the photographic subject or the edge direction of images, there are times when a large error occurs in the distance accuracy of the amount of shift Δ′ obtained by means of image matching.

In order to prevent such an error in the distance accuracy, the arrangement of the various types of optical filters in the filter array 40 needs to satisfy a first condition and a second condition explained below.

The following explanation is about the first condition. For example, in the filter array 40, consider a case in which a particular optical filter does not have optical filters of the same type (the same color) in the vicinity. In this case, as described above, since the amount of shift Δ′ between the microlens images 30 depends on the distance A to the photographic subject, if an image of the photographic subject is formed only between the microlenses 120 disposed in the vicinity of each other, then the distance cannot be measured. Thus, each optical filter needs to have optical filters of the same color in the vicinity. This condition is set as the first condition.

The following explanation is given for the second condition. Herein, the second condition is related to the directional dependency of the color filter arrangement as far as the distance accuracy is concerned. In the example illustrated in (a) in FIG. 13, regarding a particular optical filter, optical filters of the same color are arranged in the vicinity but only in a single axis direction. That is, in the example illustrated in (a) in FIG. 13, the optical filters of each of the RGBIr colors are linearly arranged on a color-by-color basis.

In this arrangement, if the direction of change in luminance value on the edges of a photographic subject image is parallel to the direction of the axis in which the optical filters of same colors are arranged, then it may lead to a decline in the accuracy of image matching. That is, the image processor 23 performs image matching using the microlens images 30, each of which is formed by the light passing through the optical filters of the same color. Hence, for example, if an edge of an image is parallel to the axis direction in which the optical filters of same colors are arranged, then the microlens images 30 formed adjacent to each other in that axis direction are likely to be substantially same images. In this case, it becomes difficult to perform distance measurement using image matching.

In this way, when the optical filters of same colors are lined in a single axis direction, it leads to a directional dependency in which the distance accuracy becomes dependent on the edge direction of the photographic subject. Hence, during image mapping, in order to reduce the directional dependency of the direction accuracy with respect to the edge direction, the arrangement of the optical filters in the filter array 40 is desirably such that the optical filters of same colors are present in a plurality of axis directions.

Herein, an axis is determined by three optical filters of the same color. When three optical filters of the same color are linearly aligned, they are present on a single axis. In this case, these three optical filters of the same color do not satisfy the second condition. In contrast, consider a case of a first line that joins two of the three optical filters, and consider a case of second line that joins the centers of two optical filters including optical filters other than the two optical filters mentioned above. If the first line and the second line intersect with each other, then the concerned three optical filters of the same color are present in two axis directions. In that case, the three optical filters of the same color satisfy the second condition.

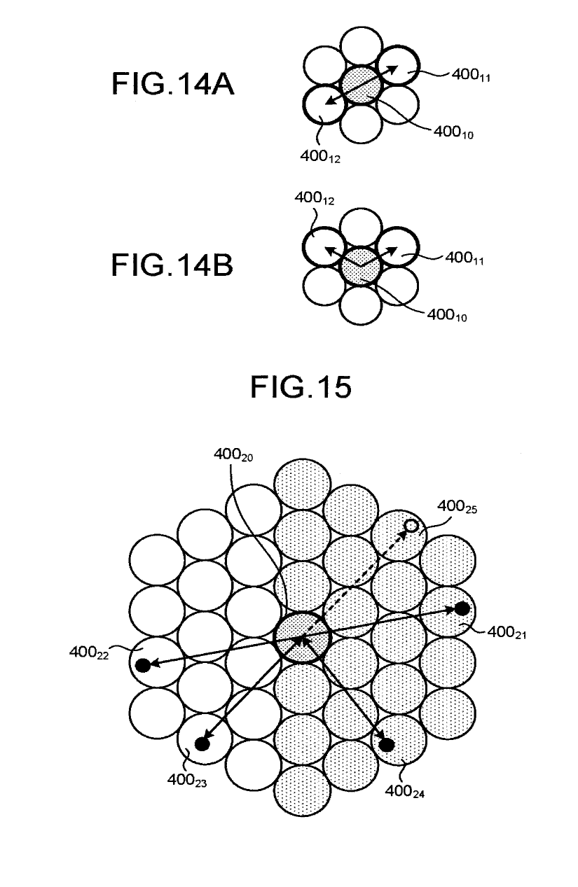

Thus, in the arrangement illustrated in FIG. 14A, an optical filter 400₁₀ and optical filters 400₁₁ and 400₁₂ of the same color are aligned in a single axis. Therefore, the optical filters 400₁₀, 400₁₁, and 400₁₂ do not satisfy the second condition. In this case, as described above, in the microlens images 30 formed due to the optical filters 400₁₀, 400₁₁, and 400₁₂; there is a possibility of a directional dependency in which the direction accuracy is dependent on the edge direction of the photographic subject.

On the other hand, in the arrangement illustrated in FIG. 148, the optical filter 400₁₀ and the optical filters 400₁₁ and 400₁₂ of the same color are not aligned in the same axis. That is, in the example illustrated in FIG. 14B, the optical filter 400₁₀ and the optical filters 400₁₁ and 400₁₂ of the same color have a first axis joining the optical filters 400₁₀ and 400₁₁ and a second axis joining the optical filters 400₁₀ and 400₁₂. Hence, the second condition is satisfied. Thus, as compared to the arrangement illustrated in FIG. 14A, the arrangement illustrated in FIG. 14B has a lower directional dependency of the direction accuracy with respect to the edge direction of the photographic subject. Therefore, the arrangement illustrated in FIG. 14B is the preferable arrangement.

Herein, consideration is given to the cyclic nature of the arrangement of optical filters of each color in the hexagonally-arranged filter array 40. In that case, the second condition, that is, the condition of having the optical filters of same colors in different axis directions can be, in other words, said to be the condition in which, regarding a particular optical filter, two optical filters that are present in the vicinity of the particular optical filter and that have the same color as the particular optical filter are not positioned to be point symmetric with respect to the particular optical filter.

That is, as a condition for a preferable optical filter arrangement in the hexagonally-arranged filter array 40, a condition can be applied that, in six neighboring optical filters of the optical filter of interest, the optical filters of at least one color are disposed in a point asymmetric manner. This condition can be set as a third condition. Thus, the third condition implies the same meaning as the second condition described above.

In the filter array 40A illustrated in FIG. 12, regarding an arbitrary optical filter, optical filters of the same color are disposed in the vicinity. Hence, the first condition is satisfied. Moreover, in six optical filters present in the vicinity of an arbitrary optical filter, the optical filters of same colors are disposed in a point asymmetric manner. Hence, the third condition is satisfied.

Explained below in concrete terms and with reference to FIG. 15 is the positional relationship of the optical filters according to the first embodiment. In FIG. 15, the range across two intervening optical filters is treated as the vicinity. That is, in the hexagonally-arranged filter array 40, regarding an optical filter 400₂₀ at the center, other optical filters (for example, an optical filter 400₂₅) that are positioned across two intervening optical filters as well as the optical filters positioned at a shorter distance from the optical filter 400₂₀ as compared to those other optical filters are all treated as the optical filters in the vicinity of the optical filter 400₂₀. In the example illustrated in FIG. 15, a hexagonal range in which seven optical filters, including the optical filter 400₂₀, are diagonally aligned is treated as the vicinity of the optical filter 400₂₀.

In FIG. 15, it is assumed that the optical filters 400₂₀ to 400₂₅ are of the same color. With the optical filter 400₂₀ considered as the center, the optical filters 400₂₁ and 400₂₂ are positioned to be point symmetric with respect to the optical filter 400₂₀. Hence, the third condition is not satisfied. In this case, the calculation for image matching is performed in a single axis direction joining the optical filters 400₂₁, 400₂₀, and 400₂₂. That leads to an increase in the directional dependency of the direction accuracy with respect to the edge direction of the photographic subject. Such a situation is not desirable. In an identical manner, the optical filters 400₂₁, 400₂₀, and 400₂₂ are also positioned in a collinear manner. Hence, image matching is performed in a single axis direction, which is not a desirable situation.

In contrast, the optical filters 400₂₃ and 400₂₄ are not positioned to be point symmetric with respect to the optical filter 400₂₀. Hence, the third condition is satisfied. Therefore, the calculation for image matching can be performed in two axis directions, namely, the axis direction joining the optical filters 400₂₀ and 400₂₃ and the axis direction joining the optical filters 400₂₀ and 400₂₄. That enables achieving reduction in the directional dependency of the direction accuracy with respect to the edge direction of the photographic subject.

Specific Example of Color Filter Arrangement According to First Embodiment

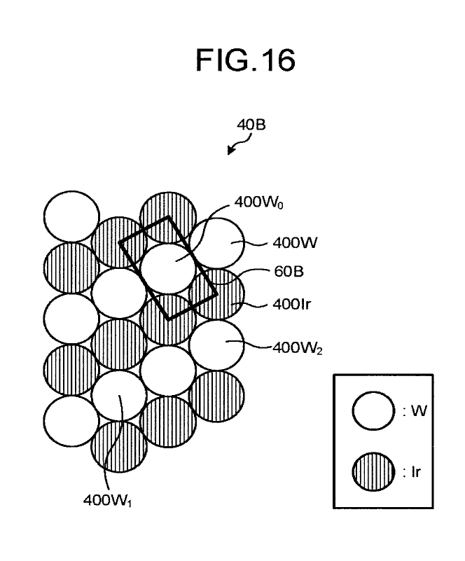

Explained below with reference to FIGS. 16 to 19 are specific examples of an optical filter arrangement in which: Ir filters are used; a condition summarizing the first to third conditions is satisfied; and the minimum magnification 1/N for reconstruction is relatively small.

In FIG. 16 is illustrated an example in which a filter array 40B is configured with optical filters 400Ir as Ir filters and optical filters 400W as white color filters. In the arrangement illustrated in FIG. 16, the color component of the Ir color and the color component of the white color have the ratio of 1:1 in the filter array 40; and a unit area 608 enclosed in a frame border serves as the smallest repeating unit.

The arrangement illustrated in FIG. 16 can be achieved when a linear arrangement of the optical filters 400Ir of Ir color and a linear arrangement of the optical filters 400W of white color are placed adjacent to each other in a repeated manner.

In the arrangement illustrated in FIG. 16, the filter array includes a plurality of second sets. Each second set includes a third array including first optical filters lined in a third direction; and includes a fourth array which includes second optical filters lined in the first direction and which is lined with the third array in a fourth direction that intersects with the third direction. Moreover, a plurality of second sets is lined in the fourth direction.

In the filter array 40B illustrated in FIG. 16, regarding an arbitrary optical filter, optical filters of the same color are disposed in the vicinity. Hence, the first condition is satisfied. However, in the filter array 408 illustrated in FIG. 16, with an arbitrary optical filter at the center, the optical filters of the same color are disposed in a point symmetric manner. Hence, the third condition is not satisfied. Regarding an optical filter 400W₀, optical filters 400W₁ and 400W₂ of the same color are disposed across one intervening optical filter from the optical filter 400W₀. Moreover, the optical filters 400W₁ and 400W₂ are positioned in a point asymmetric manner with respect to the optical filter 400W₀.

In the filter array 40B, for example, as a result of using the optical filters 400W₁ and 400W₂ that are positioned across one intervening optical filter from the optical filter 400W₀, that have the same color as the optical filter 400W₀, and that are positioned in a point asymmetric manner with respect to the optical filter 400W₀; it becomes possible to perform image matching while reducing the edge dependency.

Meanwhile, if the arrangement of the filter array 40B illustrated in FIG. 16 is compared with the arrangement of the filter array 40A illustrated in FIG. 12; then the arrangement illustrated in FIG. 12 has higher anisotropy of the microlens images of same colors and is of advantage from the perspective of the distance accuracy in image matching.

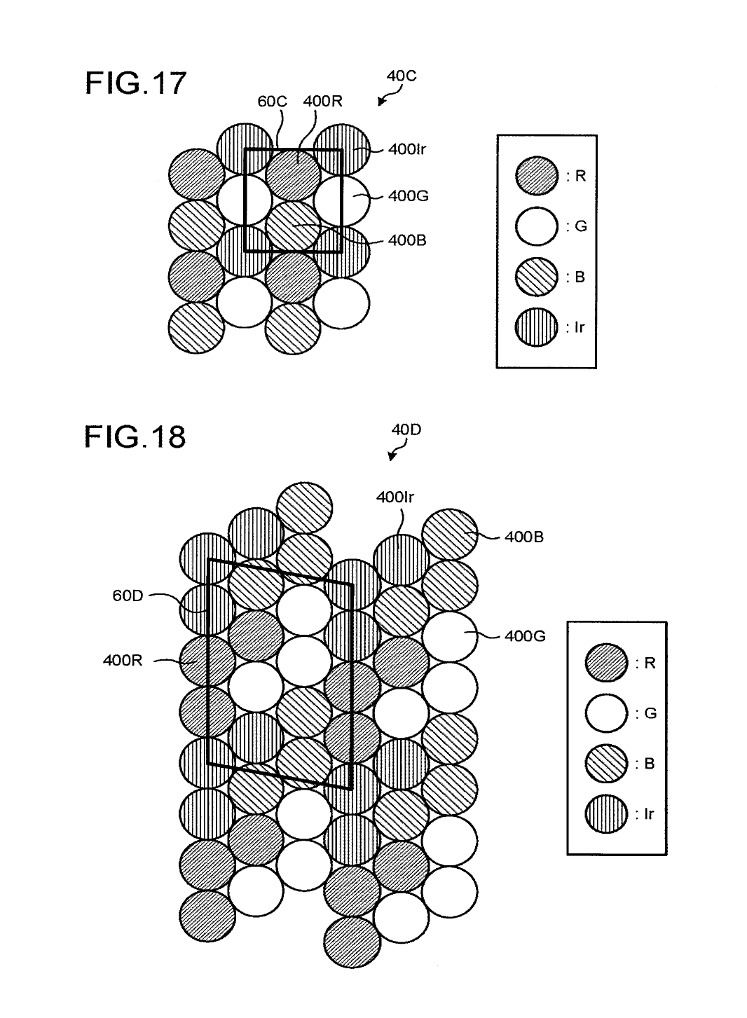

In FIGS. 17 to 19 are illustrated exemplary filter arrays 40C to 40E in each of which optical filters 400R of red color, optical filters 400G of green color, optical filters 400B of blue color, and optical filters 400Ir of Ir color are included at the ratio of 1:1:1:1. In FIG. 17 is illustrated an example of the filter array 40C that includes a single optical filter 400R, a single optical filter 400G, a single optical filter 400B, and a single optical filter 400Ir in a unit area 60C that serves as the smallest repeating unit. In the filter array 40C illustrated in FIG. 17, the optical filters 400R, 400G, 400B, and 400Ir are disposed in such a way that any two neighboring optical filters are of different types (colors). Moreover, in the arrangement illustrated in FIG. 17, the unit area 60C enclosed in a frame border serves as the smallest repeating unit.

Furthermore, in the filter array 40C illustrated in FIG. 17, in six neighboring optical filters of an arbitrary optical filter, the optical filters of the same color are disposed in a point asymmetric manner. Hence, the third condition is satisfied. However, in the filter array 40C, no arbitrary optical filter has optical filters of the same color in the vicinity thereof. Hence, the first condition is not satisfied. In such a case too, in the filter array 40C, optical filters of same colors are present at the positions separated by one and half optical filters. Thus, if the used microlens images correspond to the same-color optical filters present at the positions separated by one and half optical filters, it becomes possible to perform image matching.

In the arrangement illustrated in FIG. 17, the filter array includes a plurality of ninth arrays. Each ninth array has a plurality of first cycles lined in a seventh direction; and each first cycle includes the first optical filters, the second optical filters, the third optical filters, and the fourth optical filters lined in the seventh direction. Moreover, the ninth arrays are lined in an eighth direction that intersects with the seventh direction, and the neighboring ninth arrays are lined in the seventh direction by a shift of half a cycle.

In FIG. 18 is illustrated an example of a filter array 40D that includes three optical filters 400R, three optical filters 400G, three optical filters 400B, and three optical filters 400Ir in a unit area 60D that serves as the smallest repeating unit. In FIG. 18, the filter array 40D includes a first group in which two first color optical filters, one second color optical filter, two Ir color optical filters, and one third color optical filter are sequentially and adjacently lined in the first direction. Moreover, the filter array 40D includes a second group in which one first color optical filter, two second color optical filters, one Ir color optical filter, and two third color optical filters are sequentially and adjacently lined in the second direction. Besides, the filter array 40D further includes a third group including optical filters in the same arrangement as the first group; and includes a fourth group including optical filters in the same arrangement as the second group. In the first to fourth groups, the optical filters are lined in a parallel direction to each other. Moreover, the first to fourth groups are lined in that order in the second direction that intersects with the first direction. Herein, the first direction and the second direction form an angle of, for example, 120°. A particular optical filter included in the first group is positioned next to another optical filter that is included in the second group and that has the same color as the particular optical filter. Moreover, a particular optical filter included in the first group is separated from another optical filter, which is included in the third group and which has the same color as the particular optical filter, by three optical filters in the first direction. Furthermore, a particular optical filter included in the second group is separated from another optical filter, which is included in the fourth group and which has the same color as the particular optical filter, by three optical filters in the first direction.

In the example illustrated in FIG. 18, the first color, the second color, and the third color respectively are red color, green color, and blue color. However, the assignment of colors to the first to third colors is not limited to this example.

In the arrangement illustrated in FIG. 18, the filter array includes a plurality of fourth sets. Each fourth set includes a tenth array, an eleventh array, a twelfth array, and a thirteenth array. In the tenth array, two first optical filters, one second optical filter, two third optical filters, and one fourth optical filter are arranged in that order in a ninth direction. In the eleventh array, one first optical filter, two second optical filters, one third optical filter, and two fourth optical filters are arranged in that order in the ninth direction. In the twelfth array, two first optical filters, one second optical filter, two third optical filters, and one fourth optical filter are arranged in that order in the ninth direction. In the thirteenth array, one first optical filter, two second optical filters, one third optical filter, and two fourth optical filters are arranged in that order in the ninth direction. Moreover, the tenth array to the thirteenth array are lined in that order in a tenth direction that intersects with the ninth direction. The first optical filters in the tenth array and the first optical filter in the eleventh array come in contact in the tenth direction. Moreover, the first optical filter in the eleventh array and the first optical filters in the twelfth array are separated in the tenth direction by two and half first optical filters. Furthermore, the first optical filters in the twelfth array and the first optical filter in the thirteenth array come in contact in the tenth direction. Meanwhile, a plurality of fourth sets is lined in the tenth direction.

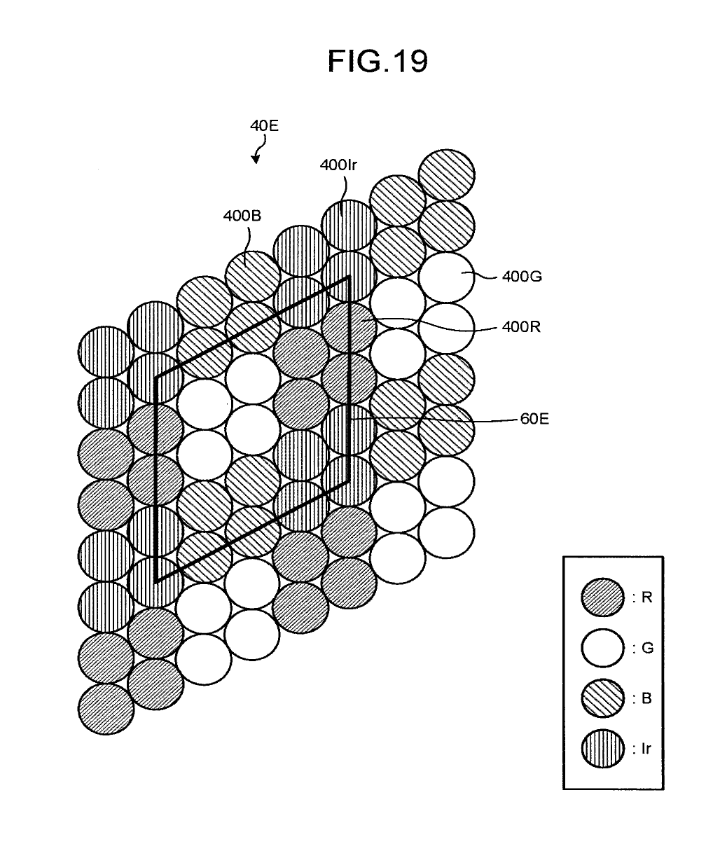

In FIG. 19 is illustrated an example of the filter array 40E that includes four optical filters 400R, four optical filters 400G, four optical filters 400B, and four optical filters 400Ir in a unit area 60E that serves as the smallest repeating unit. In the filter array 40E illustrated in FIG. 19, a group of four mutually-adjacent optical filters of the same color is formed for each color, and such groups are repeatedly arranged in such a way that the groups of same colors are not placed next to each other.

In the arrangement illustrated in FIG. 19, the filter array includes a plurality of fifth sets. Each fifth set includes a fourteenth array, a fifteenth array, a sixteenth array, and a seventeenth array. In the fourteenth array, two first optical filters and two second optical filters are alternately arranged in an eleventh direction. In the fifteenth array, two first optical filters and two second optical filters are alternately arranged in the eleventh direction. In the sixteenth array, two third optical filters and two fourth optical filters are alternately arranged in the eleventh direction. In the seventeenth array, two third optical filters and two fourth optical filters are alternately arranged in the eleventh direction. Moreover, the fourteenth array to the seventeenth array are lined in that order in a twelfth direction that intersects with the eleventh direction. Furthermore, a plurality of fifth sets is lined in the twelfth direction.

In the arrangements illustrated in FIGS. 12, 16, 17, 18, and 19; the minimum magnification 1/N for reconstruction is relatively small, and microlens images that are subjectable to image matching in the vicinity can be obtained in a plurality of axis directions. Thus, if the arrangement illustrated in any one of FIGS. 12, 16, 17, 18, and 19 is adopted, then reconstructed images of a high resolution can be obtained during the refocusing operation even in the case in which it filters are used that selectively transmit infrared light. Besides, it becomes possible to reduce the directional dependency in which the direction accuracy is dependent on the edge direction of the photographic subject.

Meanwhile, if the distance to the photographic subject is infinite or is such a long distance that it can be treated to be infinite, then the light coming from the main lens 11 and falling on the microlens array 12 becomes parallel light or a light close to parallel light. At that time, the images formed due to the microlenses 120 are all different images, thereby making it difficult to perform image matching. Thus, longer the distance to the photographic subject, greater is the difference in images formed due to the neighboring microlenses 120. Hence, image matching becomes a difficult task.

In that regard, in a configuration in which the optical filters of same colors are closely placed to each other, such as in the filter array 40E illustrated in FIG. 19; it becomes possible to deal with a case in which the photographic subject is at a far distance. Hence, such a configuration is preferable. In contrast, in the filter array 40C illustrated in FIG. 17, since the optical filters of same colors are not adjacent to each other, it is difficult to deal with a case in which the photographic subject is at a far distance. However, if the photographic subject is at a short distance, adopting the filter array 40C enables performing image matching using the optical filters of same colors that are separated by, for example, one and half optical filters. Hence, it becomes possible to achieve a higher degree of distance accuracy.

### Second Embodiment

Given below is the explanation of a second embodiment. In the second embodiment, the explanation is given about a driving method and a signal processing method for an image sensor that is suitable in a filter-array-equipped microlens having a filter array that includes Ir filters.

As described above, in an image sensor in which the microlens array 12 is used, image matching can be performed among the microlens images so as to obtain the reduction ratio N of the microlens images, and the distance A to the photographic subject can be obtained from the reduction ratio N. At that time, during image matching, greater the texture quantity of the photographic subject image, the better is the strength against the factors such as noise causing false detection.

Thus, in a captured image, it is desirable to have a high image contrast, and it is necessary that the image is not too dark. On the other hand, if the image is too bright, then a saturated area attributed to blown out highlights gets formed in the image. Hence, there exists an area in which image matching becomes difficult. In this way, in order to perform image matching in an appropriate manner, the most suitable exposure time needs to be selected.

In the first embodiment, the filter array 40 includes Ir filters that transmit the infrared light. If the same image sensor is used herein, then there are times when the most suitable exposure time is different for visible light than for infrared light. For example, even if the exposure time enables obtaining a high-contrast visible light image formed by capturing visible light, there are times when only a low-contrast infrared light image is obtained by capturing infrared light.

In that regard, in the second embodiment, in an imaging device, the exposure by an image sensor is carried out by dividing a single frame period into a first time period and a second time period that is longer than the first time period. In the second time period, the exposure is carried out for a longer period of time than the first time period, and it is possible to secure a greater number of signals output from the image sensor. As a result, with respect to an infrared light image formed by capturing infrared light, image processing can be performed in a suitable manner.

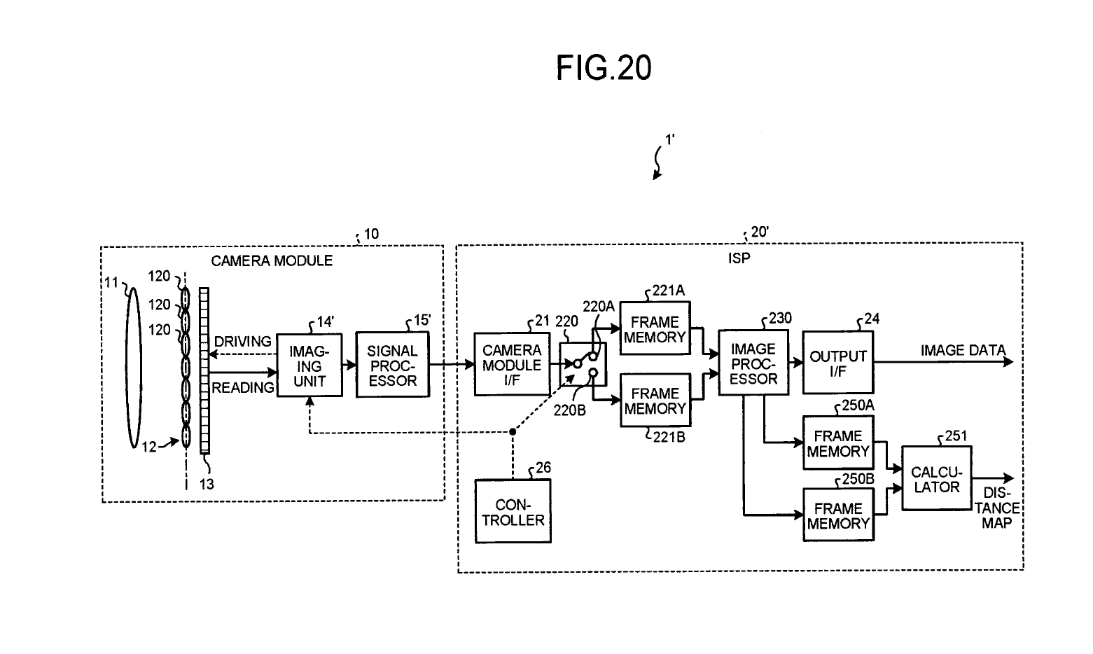

In FIG. 20 is illustrated an exemplary configuration of an imaging device 1′ according to the second embodiment. With reference to FIG. 20, the constituent elements identical to FIG. 1 are referred to by the same reference numerals, and the detailed explanation thereof is not repeated.

The imaging device 1′ includes the camera module 10 and an ISP 20′. In an identical manner to the first embodiment, the camera module 10 includes an imaging optical system including the main lens 11; a solid-state imaging device including the microlens array 12 and the image sensor 13; an imaging unit 14′; and a signal processor 15′. With respect to the microlens array 12, the filter array 40 including Ir filters is disposed on the side of the image sensor 13 or the side of the main lens 11. Herein, it is assumed that the filter array 40 includes Ir filters and optical filters of RGB colors.

The ISP 20′ includes the camera module I/F 21 and the output I/F 24; as well as includes a switch 220, frame memories 221A and 221B, an image processor 230, frame memories 250A and 250B, a calculator 251, and a controller 26.

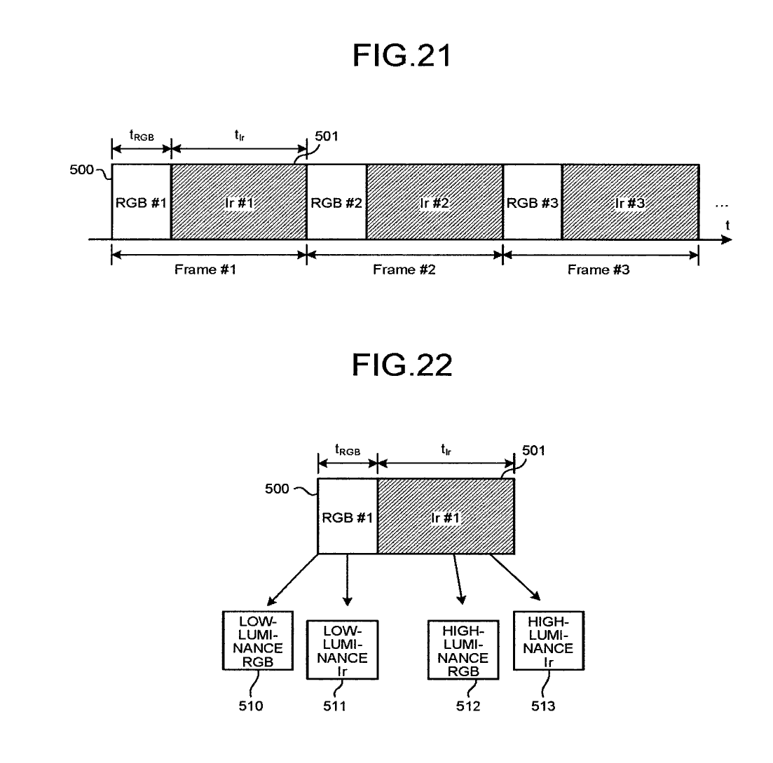

The controller 26 generates timing signals for the purpose of setting, in a single frame period, a first time period t_{RGB} and a second time period t_{Ir} that is longer than the first time period t_{RGB}. For example, as illustrated in FIG. 21, the controller 26 generates timing signals in such a way that a single frame is divided into the first time period t_{RGB} and the second time period t_{Ir}. For example, the first time period t_{RGB} is set to a period of time in which the exposure with respect to the light of RGB colors is appropriately performed. In an identical manner, the second time period t_{Ir} is set to a period of time in which the exposure with respect to infrared light is appropriately performed. Then, the controller 26 provides the imaging unit 14′ and the switch 220 with frames Frame #1, Frame #2, . . . in series.

In the example illustrated in FIG. 21, in a single frame, the first time period t_{RGB} is set to be at the leading end. However, that is not the only possible case. Alternatively, the second time period t_{Ir} can also be set to be at the leading end. Meanwhile, the first time period t_{RGB} and the second time period t_{Ir} need not represent the periods set by dividing a single frame into two, but may represent only some period of a single frame.

The imaging unit 14′ reads, in a single frame period and according to the provided timing signals, the electrical charge from the image sensor 13 during the first time period t_{RGB}; converts the electrical charge into electrical signals; and outputs the electrical signals. With respect to the electrical signals during the first time period t_{RGB}, the signal processor 15′ performs predetermined signal processing such as gain adjustment, noise removal, and amplification; performs A/D conversion with respect to the processed electrical signals; and outputs them as image data 500 of a RAW image. Then, the image data 500, which corresponds to the first time period t_{RGB} and which is output by the signal processor 15′, is sent from the camera module 10 to the ISP 20′; and is input to the switch 220 via the camera module I/F 21.

In the switch 220, either a selection output terminal 220A or a selection output terminal 220B is selected depending on the timing signals provided from the controller 26. Herein, during the first time period t_{RGB}, it is assumed that the selection output terminal 220A is selected. Accordingly, the image data 500, which corresponds to the first time period t_{RGB} and which is input to the switch 220, is stored in the frame memory 221A.

During the second time period t_{Ir} too, identical operations are performed. That is, after performing reading from the image sensor 13 during the first time period t_{RGB}, the imaging unit 14′ reads the electrical charge from the image sensor 13 during the second time period t_{Ir} according to the timing signals provided from the controller 26; converts the electrical charge into electrical signals; and outputs the electrical signals. With respect to the electrical signals during the second time period t_{Ir}, the signal processor 15′ performs predetermined signal processing mentioned above; performs A/D conversion with respect to the processed electrical signals; and outputs them as image data 501 of a RAW image. Then, the image data 501 is sent from the camera module 10 to the ISP 20′, and is input to the switch 220 via the camera module I/F 21. In the switch 220, depending on the timing signals provided from the controller 26, the selection output terminal 220B is selected during the second time period t_{Ir}. Thus, the image data 501, which is input to the switch 220, is stored in the frame memory 221B.

The image processor 230 performs image processing with respect to the image data 500 which is stored in the frame memory 221A, and the image data 501, which is stored in the frame memory 221B. As a result of performing the image processing, the image processor 230 can obtain four types of image data from the image data of pixels of RGBIr colors included in the image data 500 and the image data 501.

That is, as illustrated in FIG. 22, from the image data 500 obtained due to the exposure during the first time period t_{RGB}, low-luminance image data 510 of RGB colors and low-luminance image data 511 of infrared light is obtained. Similarly, from the image data 501 obtained due to the exposure during the second time period t_{Ir}, high-luminance image data 512 of RGB colors and high-luminance image data 513 of infrared light is obtained.

If the first time period t_{RGB} is set to be appropriate for the exposure of RGB colors, then the low-luminance RGB image data 510 serves as RGB image data having an appropriate contrast. Moreover, the high-luminance infrared-light image data 513 is likely to be infrared-light image data having an appropriate contrast. Furthermore, if the low-luminance RGB image data 510 and the high-luminance RGB image data 512 are combined, then it is possible to obtain RGB image data having a wide dynamic range. In an identical manner, if the low-luminance infrared-light image data 511 and the high-luminance infrared-light image data 513 are combined, then it is possible to obtain infrared-light image data having a wide dynamic range.

The image processor 230 selects, for example, a single set of image data from among the sets of image data 510 to 513, and outputs the selected image data to the outside via the output I/F 24. Herein, the image processor 230 can select a set of image data in response to a user operation performed using an operating unit (not illustrated) or based on contrast information obtained by analyzing the sets of image data.

Moreover, the image processor 230 stores the image data 500 and the image data 501 in the frame memories 250A and 250B, respectively. The calculator 251 performs distance calculation based on the sets of image data 500 and 501 stored in the frame memories 250A and 250B, respectively; and creates a distance map by obtaining the distance value for each microlens image 30.

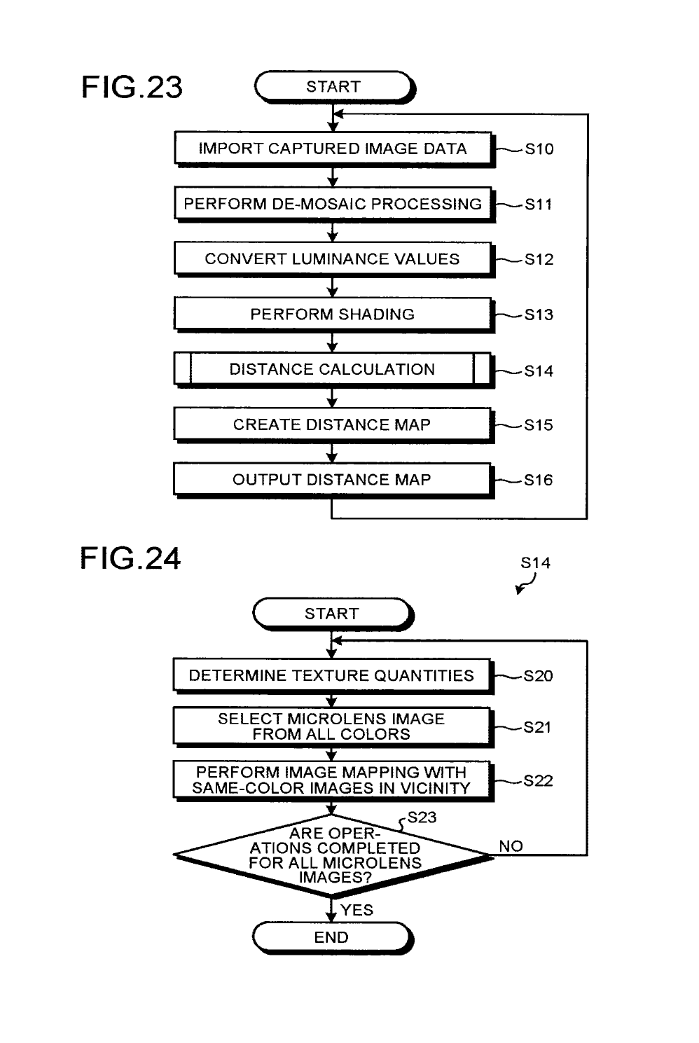

Explained below with reference to FIGS. 23 and 24 is the distance calculation performed by the calculator 251. In FIG. 23 is schematically illustrated a flow of operations performed in the ISP 20′. Firstly, according to the first time period t_{RGB} and the second time period t_{Ir}, the ISP 20′ imports the sets of image data 500 and 501, which are RAW images, from the camera module 10 (Step S10). The imported sets of image data 500 and 501 are stored in the frame memories 221A and 221B, respectively.

Then, with respect to the sets of image data 500 and 501 stored in the frame memories 221A and 221B, respectively; the image processor 230 performs de-mosaic processing and obtains RGBIr pixel values for each pixel (Step S11). Subsequently, for each of the sets of image data 500 and 501, the image processor 230 converts each pixel value into a luminance value (Step S12). At that time, based on the sets of image data 500 and 501, the image processor 230 converts pixel values into luminance values for each of the sets of image data 510 to 513.

Then, with respect to each of the sets of image data 510 to 513 after conversion to luminance values, the image processor 230 performs shading (Step S13), and stores the post-shading sets of image data 510 to 513 in the frame memories 250A and 250B. That is, of the post-shading image data, the image processor 230 stores the sets of image data 510 and 511, which are based on the image data 500, in the frame memory 250A; and stores the sets of image data 512 and 513, which are based on the image data 501, in the frame memory 250B.

Based on the sets of image data 510 to 513 read from the frame memories 250A and 250B, the calculator 251 performs distance calculation for each microlens image 30. At that time, for each of the sets of image data 510 to 513, the calculator 251 obtains the texture quantity. Then, based on the obtained texture quantities, the calculator 251 performs image matching by selecting appropriate data from the sets of image data 510 to 513, and calculates the distances.

Explained below with reference to a flowchart illustrated in FIG. 24 is an example of the distance calculation performed by the calculator 251 at Step 214. The calculator 251 performs texture quantity determination for each of the sets of image data 510 to 513 read from the frame memories 250A and 250B (Step S20). That is, regarding each of the sets of image data 510 to 513, the calculator 251 obtains the texture quantity for each microlens image 30. Then, according to the obtained texture quantities, the calculator 251 determines the set of image data, from among the sets of image data 510 to 513, to be used in image matching.

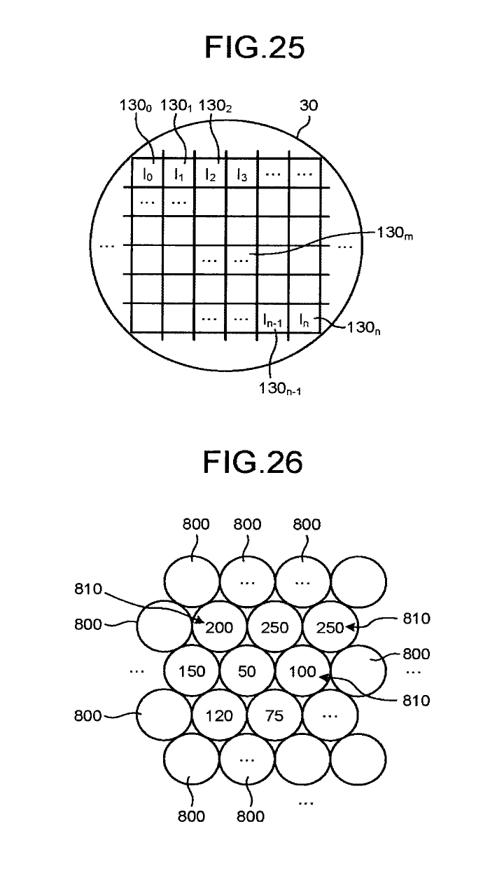

Explained below with reference to FIG. 25 is an exemplary method of calculating the texture quantity of each microlens image 30. For example, in the low-luminance RGB image data 510, the calculator 251 focuses on an arbitrary microlens image 30 (called the microlens image 30 of interest) and calculates dispersion σ₀ of luminance values I₀, I₁, I₂, . . . , and Iₙ of pixels 130₀, 130₁, 130₂, . . . , 130ₘ, . . . , 130ₙ₋₁, and 130ₙ. This dispersion σ₀ serves as the texture quantity of the microlens image 30 of interest in the image data 510.

However, the texture quantity of the microlens image 30 is not limited to the dispersion σ₀. Alternatively, for example, as the texture quantity of the microlens image 30, it is possible to use the value obtained by dividing the maximum value of the luminance values of the pixels 130₀ to 130ₙ, which are included in the microlens value 30, by the minimum value of those luminance values.

Regarding the other sets of image data 511 to 513 too, with the microlens images 30 corresponding to the microlens image 30 of interest also treated as the microlens images 30 of interest, the calculator 251 calculates dispersions σ₁, σ₂, and σ₃, respectively, of the pixels 130₀ to 130ₙ included in the respective microlens images 30 of interest. Then, the calculator 251 compares the dispersions σ₀ to σ₃ obtained from the microlens images 30 of interest in the sets of image data 510 to 513, and obtains σ as the greatest dispersion.

Then, from among the microlens images 30 of interest of the sets of image data 510 to 513, the calculator 251 selects the microlens image 30 of interest for which the greatest dispersion σ is obtained at Step S20 (Step S21).

Subsequently, from among the sets of image data 510 to 513 stored in the frame memories 250A and 250B, in the image data that includes the microlens image 30 of interest selected at Step S21, the calculator 251 performs image matching using the microlens images 30 positioned in the vicinity of the microlens image 30 of interest and having the same color as the microlens image 30 of interest (Step S22).

For example, at Step S21, of the dispersions σ₀ to σ₃ of the microlens images 30 of interest included in the sets of image data 510 to 513, the dispersion σ₀ of the microlens image 30 of interest included in the image data 510 is assumed to have the greatest value, and this microlens image 30 of interest is assumed to be corresponding to the optical filter 400R of red color. In this case, in the image data 510, the calculator 251 performs image matching between the microlens images 30 that are positioned in the vicinity of the microlens image 30 of interest and that correspond to the optical filters 400R of red color.

As a result of performing image matching, the calculator 251 obtains the inter-microlens amount of shift Δ′, and calculates the reduction ratio N according to Equation (7) given earlier and using the known inter-microlens center distance L. Then, the calculator 251 applies the reduction ratio N to Equation (4) or Equation (6) given earlier and obtains the distance A to the photographic subject.

Subsequently, the calculator 251 determines whether or not the operations from Steps S20 to S22 are completed for all microlens images 30 (Step 323). If it is determined that the operations are yet to be performed for any microlens image 30 (No at Step S23), then the system control returns to Step S20, and the operations from Steps S20 to S22 are performed for the next microlens image 30 as the microlens image 30 of interest.

When it is determined that the operations are completed for all microlens images 30 (Yes at Step S23), the system control exits the flowchart illustrated in FIG. 24 and proceeds to Step S15 illustrated in FIG. 15.

Then, the calculator 251 creates a distance map according to the distance value calculated for each microlens image 30 at Step S14 (Step S15). As schematically illustrated in FIG. 26, in the distance map according to the second embodiment, distance values 810 obtained for the microlens images 30 are associated to areas 800 in the images corresponding to the microlenses 120 of the microlens array 12. Subsequently, the calculator 251 outputs the distance map (Step S16).

As described above, in the imaging device 1′, a single frame period is divided into the first time period t_{RGB} and the second time period t_{Ir}, and the respective sets of image data 500 and 501 are obtained. However, that is not the only possible case. Alternatively, in the imaging device 1′, without dividing a single frame period, exposure is performed for only one period and image data is obtained that contains microlens images formed by RGB colors as well as microlens images formed by infrared light. In this case, for example, if the photographic subject is sufficiently bright, the calculator 251 can perform image matching using the microlens images formed by RGB colors. However, if the photographic subject is dark, the calculator 251 can perform image matching using the microlens images formed by infrared light.

In the case of performing exposure for a single period of time without dividing a single frame period, the imaging device 1′ may not include the controller 26 that generates timing signals, the switch 220, one of the frame memories 221A and 221B, and one of the frame memories 250A and 250B.

According to the second embodiment, distance calculation is done not only using the microlens images formed by RGB colors but also using the microlens images formed by infrared light. Hence, distance calculation of a high degree of accuracy can be performed for various photographic subjects.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A filter-array-equipped microlens comprising:
a filter array including a plurality of first optical filters for selectively transmitting light of an infrared region and a plurality of second optical filters for selectively transmitting light of a first visible wavelength region; and
a microlens array including a plurality of microlenses each corresponding to any one of the first optical filters and the second optical filters.

2. The filter-array-equipped microlens according to claim 1, wherein
the first optical filters include a first filter, a second filter arranged closest to the first filter, and a third filter arranged closest to the first filter with the exception of the second filter, and
the second filter and the third filter are disposed in a point asymmetric manner with respect to the first filter.

3. The filter-array-equipped microlens according to claim 1, wherein the filter array further includes
a plurality of third optical filters for selectively transmitting light of a second visible wavelength region different from the first visible wavelength region, and
a plurality of fourth optical filters for selectively transmitting light of a third visible wavelength region different from the first visible wavelength region and the second visible wavelength region.

4. The filter-array-equipped microlens according to claim 1, wherein
the filter array includes a plurality of first sets,
each of the first sets includes a first array in which two of the first optical filters and two of the second optical filters are alternately arranged in a first direction and including a second array in which two of the first optical filters and two of the second optical filters are alternately arranged in the first direction and which is lined with the first array in a second direction that intersects with the first direction,
the first array and the second array are lined in the first direction by a shift of one and half of the first optical filter, and
the first sets are lined in the second direction.

5. The filter-array-equipped microlens according to claim 1, wherein
the filter array includes a plurality of second sets,
each of the second sets includes
a third array which includes first optical filters lined in a third direction, and
a fourth array which includes second optical filters lined in the first direction and which is lined with the third array in a fourth direction that intersects with the third direction, and
the second sets are lined in the fourth direction.

6. The filter-array-equipped microlens according to claim 3, wherein
the filter array includes a plurality of third sets,
each of the third sets includes
a fifth array which includes first optical filters lined in a fifth direction,
a sixth array which includes second optical filters lined in the fifth direction and which is lined with the fifth array in a sixth direction that intersects with the fifth direction,
a seventh array which includes third optical filters lined in the fifth direction and which is lined with the sixth array in a sixth direction, and
an eighth array which includes fourth optical filters lined in the fifth direction and which is lined with the seventh array in the sixth direction, and
the third sets are lined in the sixth direction.

7. The filter-array-equipped microlens according to claim wherein
the filter array includes a plurality of ninth arrays,
each of the ninth arrays has a plurality of first cycles lined in a seventh direction,
each of the first cycles includes the first optical filters, the second optical filters, the third optical filters, and the fourth optical filters lined in the seventh direction,
the ninth arrays are lined in an eighth direction that intersects with the seventh direction, and
the adjacent ninth arrays are lined in the seventh direction by a shift of half a cycle.

8. The filter-array-equipped microlens according to claim 3, wherein
the filter array includes a plurality of fourth sets,
the fourth sets include
a tenth array in which two first optical filters, one second optical filter, two third optical filters, and one fourth optical filter are arranged in order in a ninth direction,
an eleventh array in which one first optical filter, two second optical filters, one third optical filters, and two fourth optical filters are arranged in order in the ninth direction,
a twelfth array in which two first optical filters, one second optical filter, two third optical filters, and one fourth optical filter are arranged in order in the ninth direction, and
a thirteenth array in which one first optical filter, two second optical filters, one third optical filter, and two fourth optical filters are arranged in order in the ninth direction,
the tenth array, the eleventh array, the twelfth array, and the thirteenth array are lined in order in a tenth direction that intersects with the ninth direction,
the first optical filters in the tenth array and the first optical filter in the eleventh array come in contact in the tenth direction,
the first optical filter in the eleventh array and the first optical filters in the twelfth array are separated in the tenth direction by a shift of two and half of the first optical filter,
the first optical filters in the twelfth array and the first optical filter in the thirteenth array come in contact in the tenth direction, and
the fourth sets are lined in the tenth direction.

9. The filter-array-equipped microlens according to claim 3, wherein
the filter array includes a plurality of fifth sets,
the fifth sets include
a fourteenth array in which two of the first optical filters and two of the second optical filters are alternately arranged in an eleventh direction,
a fifteenth array in which two of the first optical filters and two of the second optical filters are alternately arranged in the eleventh direction,
a sixteenth array in which two of the third optical filters and two of the fourth optical filters are alternately arranged in the eleventh direction, and
a seventeenth array in which two of the third optical filters and two of the fourth optical filters are alternately arranged in the eleventh direction,
the fourteenth array, the fifteenth array, the sixteenth array, and the seventeenth array are lined in order in a twelfth direction that intersects with the eleventh direction, and
the fifth sets are lined in the twelfth direction.

10. The filter-array-equipped microlens according to claim 4, wherein the first optical filters and the second optical filters are arranged in a hexagonal array.

11. The filter-array-equipped microlens according to claim 5, wherein the first optical filters and the second optical filters are arranged in a hexagonal array.

12. The filter-array-equipped microlens according to claim 6, wherein the first optical filters, the second optical filters, the third optical filters, and the fourth optical filters are arranged in a hexagonal array.

13. The filter-array-equipped microlens according to claim 7, wherein the first optical filters, the second optical filters, the third optical filters, and the fourth optical filters are arranged in a hexagonal array.

14. The filter-array-equipped microlens according to claim 8, wherein the first optical filters, the second optical filters, the third optical filters, and the fourth optical filters are arranged in a hexagonal array.

15. The filter-array-equipped microlens according to claim 9, wherein the first optical filters, the second optical filters, the third optical filters, and the fourth optical filters are arranged in a hexagonal array.

16. A solid-state imaging device comprising:
the filter-array-equipped microlens according to claim 1;
a main lens configured to guide light coming from a photographic subject to the microlens array; and
an image sensor configured to receive the light after passing through the main lens, the microlens array, and the filter array.

17. The solid-state imaging device according to claim 16, further comprising:
a controller configured to control a reading timing of an image signal from the image sensor; and
a signal processor configured to perform signal processing with respect to the image signal.

18. The solid-state imaging device according to claim 17, wherein the controller performs control in such a way that reading of the image signal from the image sensor is performed in a first time period and in a second time period, which is longer than the first time period, within a single frame period.
